(19) United States
(12) Patent Application Publication
(10) Pub. No.: US 2013/0240037 A1
(43) Pub. Date: Sep. 19, 2013

(54) SOLAR CELL MODULE AND SOLAR GENERATOR

(71) Applicant: Hideomi Yui, Osaka-shi (JP)

(72) Inventor: Hideomi Yui, Osaka-shi (JP)

(73) Assignee: SHARP KABUSHIKI KAISHA, Osaka-shi, Osaka (JP)

(21) Appl. No.: 13/988,927

(22) PCT Filed: Nov. 21, 2011
(86) PCT No.: PCT/JP2011/076808

§ 371 Date: May 22, 2013

(30) Foreign Application Priority Data
Nov. 24, 2010 (JP) 2010-261688

(51) Int. Cl. H01L 31/052

(52) U.S. Cl. CPC H01L 31/0525
USPC 136/259

(57) ABSTRACT

A solar cell module according to an aspect of the present invention includes a light guide module including a first light guide and a second light guide that are disposed so as to face each other and a low-refractive-index layer that is disposed between the first light guide and the second light guide; and a solar cell that receives light emitted from the light guide module. A second main surface of the first light guide includes a first reflecting surface that reflects the first light beam and changes a propagation direction of the first light beam, which has entered through the first main surface of the first light guide. A second main surface of the second light guide includes a second reflecting surface that reflects the second light beam and changes a propagation direction of the second light beam, which has entered through the first main surface of the first light guide, has passed through the first light guide 4, has been refracted by the low-refractive-index layer, and has entered the second light guide.

### TECHNICAL FIELD

The present invention relates to a solar cell module and a solar generator.

This application claims the priority of Japanese Patent Application No. 2010-261688, filed Nov. 24, 2010, the entire contents of which are incorporated herein by reference.

### BACKGROUND ART

Existing solar generators generally include a plurality of solar panels that are arranged in a plane so as to be oriented toward the sun. For example, solar generators of a known type include a rack that is mounted on the roof of a building and a plurality of solar panels that are attached to the rack so as to be arranged in a plane. In general, solar panels are made of an opaque semiconductor, and therefore the solar panels cannot be arranged in a stack. Therefore, solar panels having large areas are needed in order that a solar generator can have high electric power.

However, due to limitation on an installation space such as a roof, the amount of electric power obtainable by a solar generator has been limited.

For this reason, there has been proposed a solar cell including an optical concentrator for guiding incident sunlight to the solar cell (see PTL 1 below). The solar cell described in PTL 1 includes a light-transmitting member having a substantially right-triangular shape in side view. A plurality of V-shaped grooves are formed in the light-transmitting member, and a solar cell is attached to an end surface of the light-transmitting member.

### CITATION LIST

### Patent Literature

PTL 1: Japanese Unexamined Patent Application Publication No. 2004-47752

### SUMMARY OF INVENTION

### Technical Problem

However, with the technology described in PTL 1, in a case where a light-guide member has a large size, an incident light beam is reflected a plurality of times by reflecting surfaces of the V-shaped grooves while the incident light beam propagates through the light-transmitting member before being concentrated on the end surface. Thus, the reflection angle of the incident light beam at the reflecting surfaces changes, the incident light beam fails to satisfy the conditions for total internal reflection at one of the reflecting surfaces, and the incident light beam leaks to the outside. As a result, the efficiency with which light is guided to the solar cell is decreased, and the power generation efficiency is decreased.

An object of the present invention, which has been made in order to solve the above problem, is to provide a solar cell module that can prevent decrease in the power generation efficiency and a solar generator including the solar cell module.

### Solution to Problem

In order to achieve the object, a solar cell module according to an embodiment of the present invention includes a light guide module including a first light guide and a second light guide that are disposed so as to face each other and a low-refractive-index layer that is disposed between the first light guide and the second light guide; and a solar cell that receives light emitted from the light guide module. The first light guide has a first main surface, a second main surface, and a first end surface that is connected to the first main surface and the second main surface, and the first light guide allows a first light beam from the outside to enter thereinto through the first main surface, to propagate therethrough, and to be emitted from the first end surface. The second light guide has a first main surface, a second main surface, and a first end surface that is connected to the first main surface and the second main surface, and the second light guide allows a second light beam that has passed through the first light guide to enter thereinto through the first main surface of the second light guide, to propagate therethrough, and to be emitted from the first end surface of the second light guide. The low-refractive-index layer has a refractive index that is lower than a refractive index of any of the first light guide and the second light guide. The solar cell receives the first light beam emitted from the first end surface of the first light guide and the second light beam emitted from the first end surface of the second light guide. The second main surface of the first light guide includes a first reflecting surface that reflects the first light beam and changes a propagation direction of the first light beam, which has entered through the first main surface of the first light guide. The second main surface of the second light guide includes a second reflecting surface that reflects the second light beam and changes a propagation direction of the second light beam, which has entered through the first main surface of the first light guide, has passed through the first light guide, has been refracted by the low-refractive-index layer, and has entered the second light guide.

In the solar cell module, the second main surface of the first light guide may include a first light-direction changer that reflects the first light beam and changes the propagation direction of the first light beam, which has entered through the first main surface of the first light guide. The first light-direction changer has a first inclined surface that is inclined at a first inclination angle with respect to the second main surface of the first light guide, and the first inclined surface serves as the first reflecting surface for reflecting the first light beam, which has entered through the first main surface of the first light guide.

In the solar cell module, the first main surface of the second light guide may include a second light-direction changer that reflects a third light beam that has entered through the second main surface of the second light guide and that changes a propagation direction of the third light beam. The second light-direction changer has a second inclined surface that is inclined at a second inclination angle with respect to the first main surface of the second light guide, and the second inclined surface reflects the third light beam, which has entered through the second main surface of the second light guide.

In the solar cell module, the first inclination angle may be equal to the second inclination angle.

In the solar cell module, the second inclination angle may be larger than the first inclination angle.

In the solar cell module, the first main surface of the first light guide may be a flat surface, and the second main surface of the second light guide may be a flat surface that is parallel to the first main surface.

In the solar cell module, the refractive index of the first light guide may be equal to the refractive index of the second light guide.

In the solar cell module, the refractive index of the second light guide may be smaller than the refractive index of the first light guide.

The solar cell module may include a spacer that is disposed between the first light guide and the second light guide, the spacer maintaining a distance between the first light guide and the second light guide.

In the solar cell module, the low-refractive-index layer may be an air layer.

In the solar cell module, the first light guide may have a second end surface that is connected the first main surface and the second main surface and that faces the first end surface. The first light-direction changer may include a first-end-side reflector that reflects a fourth light beam toward the first end surface and a second-end-side reflector that reflects a fifth light beam toward the second end surface, the fourth light beam having entered through the first main surface of the first light guide, and the fifth light beam having entered through the first main surface of the first light guide.

In the first light-direction changer of the solar cell module, the area of a reflecting surface of the first-end-side reflector may be equal to the area of a reflecting surface of the second-end-side reflector.

The solar cell module may include a plurality of light guide modules each having the same structure as the light guide module, the plurality of light guide modules being disposed so as to face each other.

A solar generator according to another embodiment of the present invention includes the solar cell module.

### Advantageous Effects of Invention

With the present invention, a solar cell module that can prevent decrease in the power generation efficiency and a solar generator including the solar cell module can be provided.

### BRIEF DESCRIPTION OF DRAWINGS

FIG. 1 is a perspective view of a solar generator according to a first embodiment of the present invention.

FIG. 2 is a sectional view of the solar generator according to the embodiment.

FIG. 3 is a sectional view of a solar cell module according to the embodiment.

FIG. 4 illustrates the function of a reflecting surface of the solar cell module according to the embodiment.

FIG. 5 illustrates the result of simulation of how sunlight is extracted in the solar cell module according to the embodiment.

FIG. 6 is a graph representing the relationship between the absorption wavelength of a solar cell and the intensity/absorption sensitivity.

FIG. 7 is a sectional view of a first modification of the solar cell module according to the embodiment.

FIG. 8 is a perspective view of a solar cell module according to a second embodiment of the present invention.

FIG. 9 illustrates the function of a reflecting surface of the solar cell module according to the embodiment.

FIG. 10 is a perspective view of a solar cell module according to a third embodiment of the present invention.

FIG. 11 illustrates the function of a reflecting surface of the solar cell module according to the embodiment.

FIG. 12 is a perspective view of a solar generator according to a fourth embodiment of the present invention.

FIG. 13 is a sectional view of the solar generator according to the embodiment.

FIG. 14 is a perspective view of a solar generator according to a fifth embodiment of the present invention.

FIG. 15 is a sectional view of the solar generator according to the embodiment.

FIG. 16 is a table showing the result of simulation of the sunlight extraction ratio.

### DESCRIPTION OF EMBODIMENTS

### First Embodiment

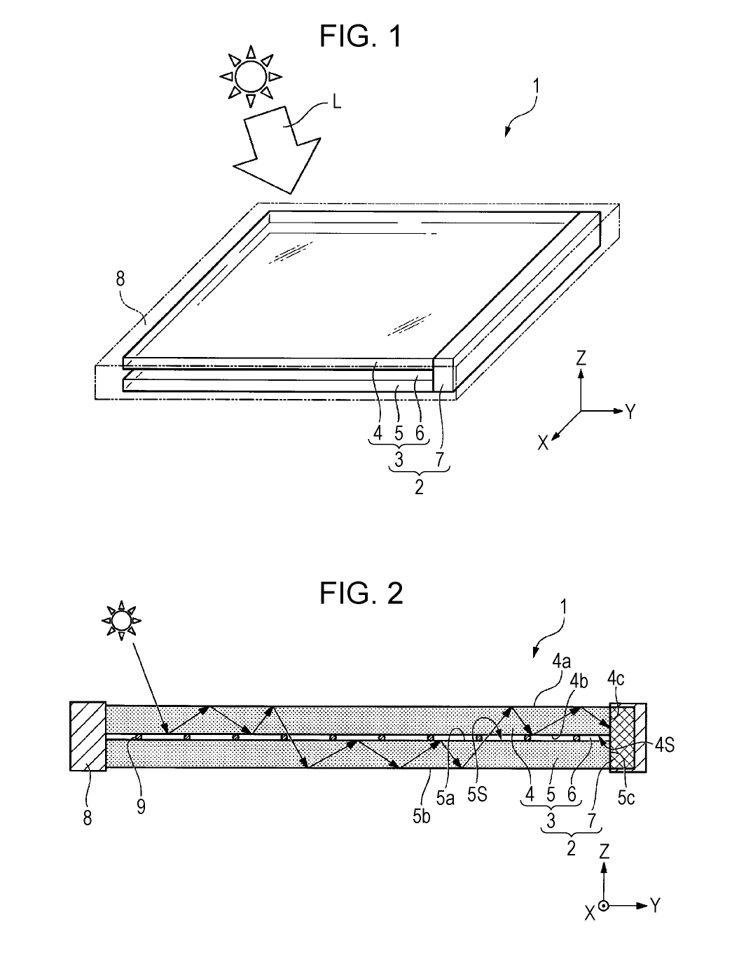

Referring to FIGS. 1 to 6, a first embodiment of the present invention will be described.

In the present embodiment, a solar generator including a solar cell module that is mounted in a support frame will be described.

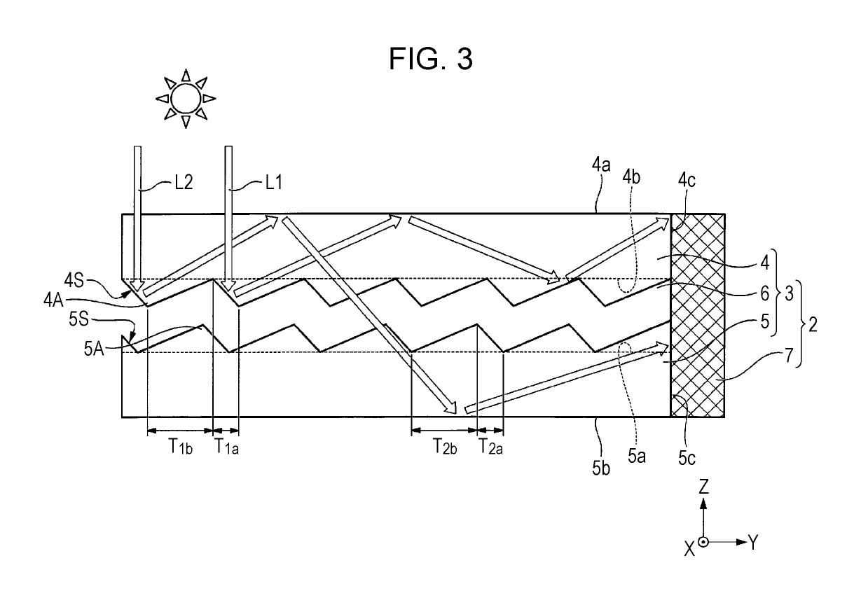

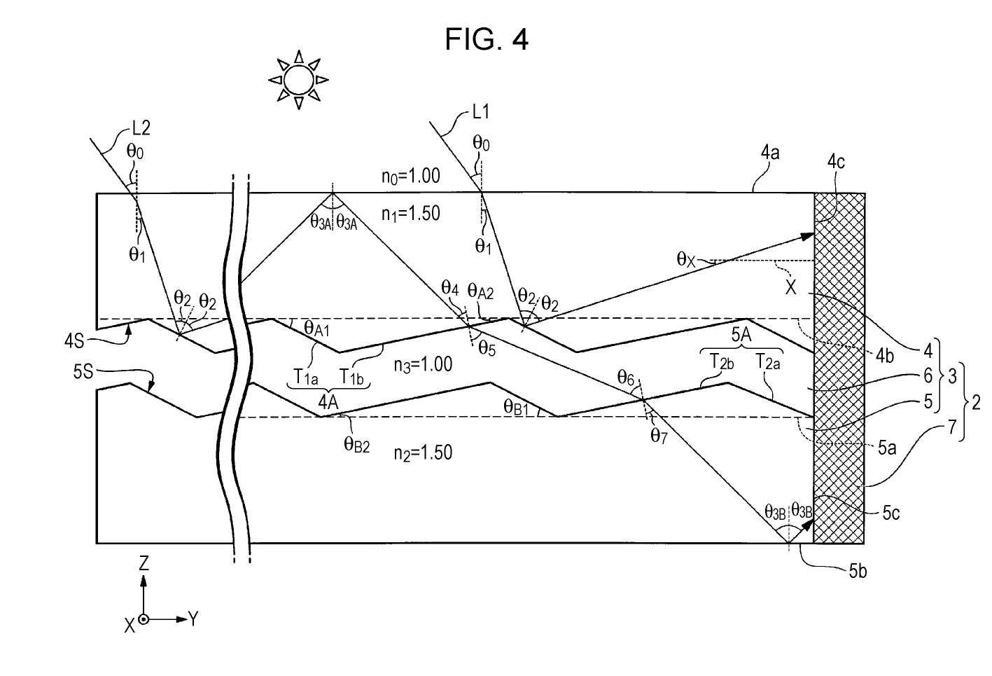

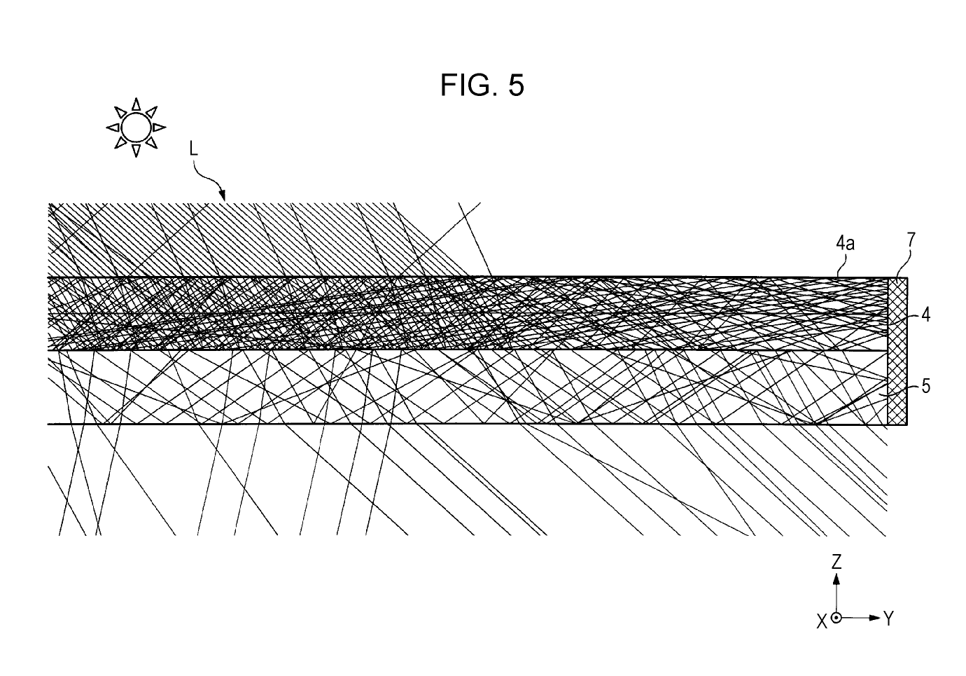

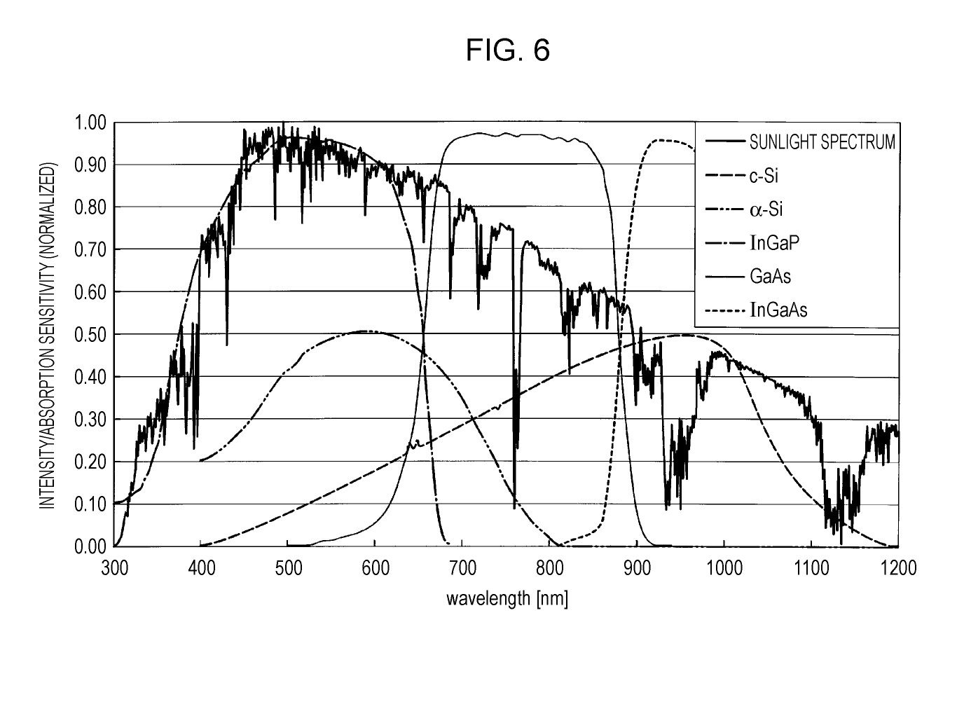

FIG. 1 is a schematic perspective view of the solar generator according to the present embodiment. FIG. 2 is a sectional view of the solar generator. FIG. 3 is a sectional view of the solar cell module. FIG. 4 illustrates the function of a reflecting surface of the solar cell module. FIG. 5 illustrates the result of simulation of how sunlight is extracted in the solar cell module. FIG. 6 is a graph representing the relationship between the absorption wavelength of a solar cell and the intensity/absorption sensitivity.

In all of the following figures, components are shown in different scales for ease of viewing the components.

As illustrated in FIG. 1, a solar generator 1 according to the present embodiment includes a solar cell module 2 and a support frame 8. The solar cell module 2 has a substantially rectangular shape in plan view. The support frame 8 is attached to the solar cell module 2 so as to surround the four sides of the solar cell module 2. The support frame 8 is fixed to the solar cell module 2 by using, for example, an acrylic adhesive.

In the case of present embodiment, the solar generator 1 is installed, for example, on the roof of a building. When sunlight is incident on the roof, electric power is generated. In addition to the solar cell module 2 and the support frame 8, the solar generator 1 may include, for example, a storage battery for storing electric power obtained by the solar cell module 2. The solar generator 1 may be configured to be mounted, for example, in a window of a building or a window of an automobile, instead of on the roof of a building.

As illustrated in FIG. 2, the solar cell module 2 includes a light guide module 3 and a solar cell 7. In the solar cell module 2, light that has entered the light guide module 3 is guided to the solar cell 7. The solar cell 7 performs photoelectric conversion and outputs electric energy.

The light guide module 3 includes a first light guide 4, a second light guide 5, and a low-refractive-index layer 6. The first light guide 4 is a transparent plate having a rectangular shape in plan view. A first light-direction changer 4S is formed on one side of the first light guide 4. A light beam L enters from a side of the first light guide 4 opposite to the side on which the first light-direction changer 4S is formed. Therefore, when installing the solar generator 1 on, for example, the roof of a building, the solar generator 1 is installed in such a way that a side of the first light guide 4 on which the first light-direction changer 4S is formed faces inward and a side opposite to the side on which the first light-direction changer 4S is formed faces outward.

The second light guide 5 is disposed so as to face the first light guide 4 with the low-refractive-index layer 6 therebetween. Spacers 9 are disposed between the first light guide 4 and the second light guide 5. The spacers 9 maintain a distance between the first light guide 4 and the second light guide 5. The refractive index n₁ of the first light guide 4 is equal to the refractive index n₂ of the second light guide 5 (n₁=n₂).

The low-refractive-index layer 6, which is disposed between the first light guide 4 and the second light guide 5, has a refractive index n₃ that is lower than that of any of the first light guide 4 and the second light guide 5. The low-refractive-index layer 6 is an air layer. It is not necessary that the layer between the first light guide 4 and the second light guide 5 be an air layer. The layer may be any layer that has a refractive index that is lower than that of any of the first light guide 4 and the second light guide 5. It is preferable that the layer be composed of a medium having a lower refractive index.

The first light guide 4 and the second light guide 5 may be made of an organic material or an inorganic material having high durability and high transparency, such as an acrylic resin, a polycarbonate resin, or glass. However, the material is not limited to these.

Any known solar cell, such as an amorphous silicon solar cell, a polycrystalline silicon solar cell, a monocrystalline silicon solar cell, or a compound-semiconductor solar cell can be used as the solar cell 7. In the present embodiment, a compound-semiconductor solar cell is used as the solar cell 7. The shape and size of the solar cell 7 are not particularly limited, provided that the solar cell 7 having the shape and size can be disposed within an end surface of the light guide module 3. The solar cell 7 is bonded to the end surface of the light guide module 3 by using, for example, aGEL (registered trademark) made by Taica Corporation.

FIG. 6 is a graph representing the relationship between the absorption wavelength of a solar cell and the intensity/absorption sensitivity. In FIG. 6, the horizontal axis represents the absorption wavelength, and the vertical axis represents the intensity/absorption sensitivity. As illustrated in FIG. 6, compound-semiconductor solar cells, such as an InGaAs solar cell, a GaAs solar cell, and an InGaAs solar cell, have peaks of the intensity/absorption sensitivity that are higher than that of any of silicon solar cells, such as a crystalline silicon (c-Si) solar cell and an amorphous silicon (a-Si) solar cell, although the light-absorption wavelength ranges of the compound-semiconductor solar cells are narrower than those of the silicon solar cells. Therefore, by using a compound-semiconductor solar cell that has a high peak of the intensity/absorption sensitivity in a specific absorption wavelength range, it is possible to convert sunlight into electricity with an efficiency higher than that of a case where a silicon solar cell is used.

Hereinafter, for convenience of description, three of the six surfaces of the first light guide 4 will be referred to as follows. A surface (parallel to the xy-plane in FIG. 1) through which light enters will be referred to as a first main surface 4a. A surface that faces the first main surface 4a and on which the first light-direction changer 4S is formed will be referred to as a second main surface 4b. A surface (parallel to the xz-plane in FIG. 1) that intersects the first main surface 4a and the second main surface 4b and from which light is emitted will be referred to as a first end surface 4c. Three of the six surfaces of the second light guide 5 will be referred to as follows. A surface (parallel to the xy-plane in FIG. 1) through which light enters and on which a second light-direction changer 5S is formed will be referred to as a first main surface 5a. A surface that faces the first main surface 5a will be referred to as a second main surface 5b. A surface (parallel to the xz-plane in FIG. 1) that intersects the first main surface 5a and the second main surface 5b and from which light is emitted will be referred to as a first end surface 5c. The first main surface 4a of the first light guide 4 is a flat surface, and the second main surface 5b of the second light guide 5 is a flat surface that is parallel to the first main surface 4a.

In the case of present embodiment, the first light guide 4 and the second light guide 5 are made of, for example, an acrylic resin. The dimensions of the first light guide 4 and the second light guide 5 are, for example, as follows: the first main surfaces 4a and 5a and the second main surfaces 4b and 5b are rectangular and have horizontal dimensions (in the x-axis direction and the y-axis direction in FIG. 2) of 250 mm×250 mm and a thickness (the dimension in the z-axis direction of FIG. 2) of 10 mm.

As illustrated in FIG. 3, the first light-direction changer 4S is disposed on the second main surface 4b side of the first light guide 4. The first light-direction changer 4S reflects light that has entered through the first main surface 4a and changes the propagation direction of the light to a direction toward the first end surface 4c. The first light-direction changer 4S includes a plurality of triangular-prism-shaped protrusions 4A that are formed on the second main surface 4b of the first light guide 4. Light beams L1 that have entered through various portions of the first main surface 4a of the first light guide 4 propagate through the first light guide 4 so as to be concentrated on a portion of the first end surface 4c on which the solar cell 7 is disposed.

The second light-direction changer 5S is disposed on the first main surface 5a side of the second light guide 5. The second light-direction changer 5S refracts light that has entered through the first main surface 5a and changes the propagation direction of the light. The second light-direction changer 5S includes a plurality of triangular-prism-shaped protrusions 5A that are formed on the first main surface 5a of the second light guide 5. Light beams that have entered through various portions of the first main surface 5a of the second light guide 5 propagate through the second light guide 5 so as to be concentrated on a portion of the first end surface 5c on which the solar cell 7 is disposed.

In the case of present embodiment, the light-direction changers (4S, 5S) are integrally formed with the light guides (4, 5) by processing the light guides. The light-direction changers can be formed by, for example, injection-molding a plastic by using dies having recesses whose shapes are the inverses of those of the protrusions (4A, 5A). Alternatively, the light-direction changers may be formed by cutting the second main surface 4b of the first light guide 4 (and the first main surface 5a of the second light guide), which are flat before being cut.

The protrusions 4A are continuously formed on the second main surface 4b of the first light guide 4. The protrusions 5A are continuously formed on the first main surface 5a of the second light guide 5. The shapes and sizes of all the protrusions 4A and 5A are the same.

The protrusions (4A, 5A) are triangular-prism-shaped. As illustrated in FIG. 3, the cross-sectional shape of each of the protrusions when the light guide (4, 5) is cut along the yz-plane is not an equilateral triangle or an isosceles triangle but is a scalene triangle.

As illustrated in FIG. 4, each of the protrusions 4A of the first light-direction changer 4S has first inclined surfaces (a steeply inclined surface T₁ₐ and a gently inclined surface T_{1b}). The steeply inclined surface T₁ₐ has a predetermined inclination angle θ_{A1} (first inclination angle) with respect to the second main surface 4b. The gently inclined surface T_{1b} has an inclination angle θ_{A2}, which is smaller than the inclination angle θₘ of the steeply inclined surface T₁ₐ, with respect to the second main surface 4b. These two first inclined surfaces T₁ₐ and T_{1b} function as a reflecting surface (first reflecting surface) for reflecting (totally internally reflecting) light that has entered through the first main surface 4a.

Each of the protrusions 5A of the second light-direction changer 5S has second inclined surfaces (a steeply inclined surface T₂ₐ and a gently inclined surface T_{2b}). The steeply inclined surface T_{z}, has a predetermined inclination angle θ_{B1} (second inclination angle) with respect to the first main surface 5a. The gently inclined surface T_{2b} has an inclination angle θ₃₂, which is smaller than the inclination angle θ_{B1} of the steeply inclined surface T₂ₐ, with respect to the first main surface 5a. These two second inclined surfaces T₂ₐ and T_{2b}, function as a refracting surface for refracting light that has entered through the first main surface 5a.

As illustrated in FIG. 4, when a sunlight beam L1 (sunlight beam that is incident at a position that is relatively near to the first end surface 4c) is incident on the first main surface 4a of the first light guide 4 at an incident angle θ₀, the sunlight beam L1 is refracted by the first main surface 4a at a refraction angle θ₁ when entering the first light guide 4. Subsequently, the light beam is incident on the steeply inclined surface T₁ₐ at an incident angle θ₂, is totally internally reflected by the steeply inclined surface T₁ₐ at a reflection angle θ₂, propagates through the first light guide 4 at an angle θₓ to an imaginary plane X that is parallel to the first main surface 4a, and is emitted toward the solar cell 7.

A sunlight beam L2 that is incident on the first main surface 4a of the first light guide 4 at a relatively remote position (sunlight beam that is incident at a position that is farther from the first end surface 4c than a position at which the sunlight beam L1 is incident) is reflected between the first main surface 4a and the second main surface 4b a larger number of times than the sunlight beam L1 while propagating through the first light guide 4.

When the sunlight beam L2 is incident on the first main surface 4a of the first light guide 4 at an incident angle θ₀, the sunlight beam L2 is refracted by the first main surface 4a at a refraction angle θ₁ when entering the first light guide 4. The light beam is incident on the steeply inclined surface T₁ₐ at an incident angle θ₂ and is totally internally reflected at a reflection angle θ₂. The light beam, which has been totally internally reflected by the steeply inclined surface T₁ₐ at the reflection angle θ₂, is reflected a predetermined times between the first main surface 4a and the second main surface 4b. Then, the light beam is incident on the first main surface 4a at an incident angle θ_{3A}, and is totally internally reflected at a reflection angle θ_{3A}. The light beam, which has been totally internally reflected by the first main surface 4a at the reflection angle θ_{3A}, is incident on the gently inclined surface T_{1b} at an incident angle θ₄, is refracted at a refraction angle θ₅, and is incident on the first main surface 5a (gently inclined surface T_{2b}) of the second light guide 5 at an incident angle θ₆. The light beam, which is incident on the gently inclined surface T_{2b} at the incident angle θ₆, is refracted by the gently inclined surface T_{2b} of the second light guide 5 at a refraction angle θ₇ when entering the second light guide 5. Subsequently, the light beam is incident on the second main surface 5b of the second light guide 5 at an incident angle θ_{2B}, is totally internally reflected by the second main surface 5b at a reflection angle θ_{2B}, propagates through the second light guide 5, and is emitted toward the solar cell 7.

Here, the incident angle θ₂, at which the light beam is incident on the steeply inclined surface T₁ₐ of the first light guide 4, changes in accordance with the inclination angle θ_{A1} of the steeply inclined surface T₁ₐ. Therefore, the inclination angle θ_{A1} of the steeply inclined surface T₁ₐ is set beforehand so that the incident angle θ₂, at which the light beam is incident on the steeply inclined surface T₁ₐ, is larger than the critical angle for the interface between the steeply inclined surface T₁ₐ and air and the light beam is totally internally reflected by the interface. The incident angle θ₄, at which the light beam is incident on the gently inclined surface T_{1b} of the first light guide 4, also changes in accordance with the inclination angle θ_{A2} of the gently inclined surface T_{1b}.

The incident angle at which the light beam is incident on the steeply inclined surface T₂ₐ of the second light guide 5 changes in accordance with the inclination angle θ_{B1} of the steeply inclined surface T₂ₐ. The incident angle θ₆, at which the light beam is incident on the gently inclined surface T_{2b} of the second light guide 5, changes in accordance with the inclination angle θ_{B2} of the gently inclined surface T_{2b}. In the present embodiment, the inclination angle θ_{A1} of the steeply inclined surface T₁ₐ of the first light guide 4 is equal to the inclination angle θ_{B1} of the steeply inclined surface T₂ₐ of the second light guide 5 (θ_{A1}=θ_{B1}). The inclination angle θ_{A2} of the gently inclined surface T_{1b} of the first light guide 4 is equal to the inclination angle θ_{B2} of the gently inclined surface T_{2b} of the second light guide 5 (θ_{A2}=^{θ}_{B2}).

To be specific, for example, it is assumed as follows: the inclination angle θ_{A1} of the steeply inclined surface T₁ₐ of the first light guide 4 is 24 degrees, the inclination angle θ_{A2} of the gently inclined surface T_{1b} of the first light guide 4 is 21 degrees, the refractive index n₁ of the first light guide 4 and the refractive index n₂ of the second light guide 5 are 1.5, and the refractive index nₒ of external air and the refractive index n₃ of the air layer 6 are 1.0. In this case, according to Snell's law, the critical angle for the interface between the air layer 6 and the steeply inclined surface T₁ₐ or the gently inclined surface T_{1b} of the first light guide 4 is 41 degrees. Here, if the incident angle θ₀, at which the sunlight beam L1 is incident on the first main surface 4a of the first light guide 4, is larger than or equal to 27 degrees, the refraction angle θ₁, at which the sunlight beam L1 is refracted when the sunlight beam L1 enters the first light guide 4, is larger than or equal to 18 degrees. Then, the incident angle θ₂, at which the light beam is incident on the steeply inclined surface T₁ₐ of the first light guide 4, is larger than or equal to 42 degrees (θ₂=θ₁+θ_{A1}). Because the incident angle θ₂ is larger than or equal to the critical angle (θ₂≧41 degrees), the light beam L1 is totally internally reflected by the steeply inclined surface T₁ₐ.

The critical angle for the interface between external air and the second main surface 5b of the second light guide 5 is also 41 degrees. Also in this case, if the incident angle θ₀, at which the sunlight beam L2 is incident on the first main surface 4a of the first light guide 4, is larger than or equal to 27 degrees, the refraction angle θ₁, at which the sunlight beam L2 is refracted when the sunlight beam L2 enters the first light guide 4, is larger than or equal to 18 degrees. Then, the incident angle θ₂, at which the light beam is incident on the steeply inclined surface T₁ₐ of the first light guide 4, is larger than or equal to 42 degrees (θ₂=θ₁+θ_{A1}). Because the incident angle θ₂ is larger than or equal to the critical angle (θ₂≧41 degrees), the light beam L2 is totally internally reflected by the steeply inclined surface T₁ₐ.

The light beam, which has been totally internally reflected by the steeply inclined surface T₁ₐ of the first light guide 4 at a reflection angle θ₂, is reflected a predetermined times between the first main surface 4a and the second main surface 4b. Then, the light beam is incident on the first main surface 4a at the incident angle θ_{3A}, and is totally internally reflected at the reflection angle θ_{3A}. Here, if the incident angle θ_{3A}, at which the light beam L2 is incident on the first main surface 4a of the first light guide 4, (the reflection angle θ_{3A}, at which the light beam L2 is reflected by the first main surface 4a) is larger than or equal to 41 degrees and smaller than 62 degrees, the incident angle θ₄, at which the light beam is incident on the gently inclined surface T_{1b} of the first light guide 4, is larger than or equal to 20 degrees and smaller than 41 degrees (θ₄=θ_{3A}−θ_{A2}). Because the incident angle θ₄ is equal to smaller than the critical angle (θ₄<41 degrees), the light beam L2 passes through the gently inclined surface T_{1b}.

If the incident angle θ₄, at which the light beam is incident on the gently inclined surface T_{1b} of the first light guide 4, is larger than or equal to 20 degrees and smaller than 41 degrees, the refraction angle θ₅, at which the light beam L2 is refracted when the light beam L2 enters the air layer 6, (the incident angle θ₆, at which the light beam L2 is incident on the gently inclined surface T_{2b} of the second light guide 5) is larger than or equal to 31 degrees and smaller than 79 degrees. Then, the refraction angle θ₇, at which the light beam L2 is refracted when the light beam L2 enters the second light guide 5, is larger than or equal to 20 degrees and smaller than 41 degrees.

In the present embodiment, the refractive index n₁ of the first light guide 4 is equal to the refractive index n₂ of the second light guide 5 (n₁=n₂). Moreover, the inclination angle of one of the first inclined surfaces of the first light guide 4 (the inclination angle θ_{A2} the gently inclined surface T_{1b}) is equal to the inclination angle of one of the second inclined surfaces of the second light guide 5 (the inclination angle θ₂₂ of the gently inclined surface T_{2b}) (θ_{A2}=θ_{B2}). Furthermore, the first main surface 4a of the first light guide 4 is a flat surface, and the second main surface of the second light guide 5 is a flat surface that is parallel to the first main surface 4a. Therefore, the reflection angle θ_{3A}, at which the light beam L2 is reflected by the first main surface 4a of the first light guide 4, is equal to the reflection angle θ_{3B}, at which the light beam L2 is reflected by the second main surface 5b of the second light guide 5 (θ_{3A}=θ_{3B}). Therefore, the light beam L2, which has been incident on the first main surface 4a of the first light guide 4 at the incident angle θ_{3A} and has been totally internally reflected at the reflection angle θ_{3A}, is incident on the second main surface 5b of the second light guide 5 at the incident angle θ_{3B}, which is equal to the reflection angle θ_{3A}, and is totally internally reflected at the reflection angle θ_{3B}. The light beam L2, which has been totally internally reflected by the second main surface 5b of the second light guide 5 at the reflection angle θ_{3B}, propagates through the second light guide 5, and is emitted toward the solar cell 7.

The above description can be summarized as follows. As illustrated in FIG. 4, the light beam L1, which is one of light beams that enter through various portions of the first light guide 4, is incident on the first main surface 4a of the first light guide 4 at a position that is relatively near to the first end surface 4c. The light beam L1 is incident on the steeply inclined surface T₁ₐ of one of the protrusions 4A, is totally internally reflected by the steeply inclined surface T₁ₐ, and is guided to the solar cell 7. The light beam L2, which is one of light beams that enter through various portions of the first light guide 4, is incident on the first light guide 4 at a position on the first main surface 4a of the first light guide 4 that is relatively far from the first end surface 4c. The light beam L2 is incident on the steeply inclined surface T₁ₐ of one of the protrusions 4A, and is totally internally reflected by the steeply inclined surface T₁ₐ. Along a path toward the solar cell 7, the light beam L2 is reflected a predetermined times and fails to satisfy the conditions for total internal reflection. Thus, the light beam L2 passes through the first light guide 4. However, the light beam L2 is totally internally reflected by the second main surface 5b of the second light guide 5, and is guided to the solar cell 7. If the second light guide 5 were not provided, all the light that has passed through the first light guide 4 would leak to the outside.

That is, in the present embodiment, the steeply inclined surface T₁ₐ of each of the protrusions 4A of the first light-direction changer 4S serves as a reflecting surface (first reflecting surface) for reflecting the light beam L1 and changing the propagation direction of the light beam 1 to a direction toward the first end surface 4c. The second main surface 5b of the second light guide 5 serves as a reflecting surface (second reflecting surface) for reflecting the light beam L2, which has passed through the first light guide 4, has been refracted by the air layer 6, and has entered the second light guide 5, and changing the propagation direction of the light beam L2 to a direction toward the first end surface 5c.

FIG. 5 illustrates the result of simulation of how sunlight is extracted in the solar cell module. As illustrated in FIG. 5, some of light beams L that have entered through the first main surface 4a of the first light guide 4 propagate through the first light guide 4, are guided to the solar cell 7, and contribute to power generation. The remainder of the light beams L are emitted from the first light guide 4, propagate through the second light guide 5, are guided to the solar cell 7, and contribute to power generation. For convenience of drawing, the air layer 6 is not illustrated in FIG. 5.

Because the solar generator 1 according to the present embodiment includes the first light guide 4 and the second light guide 5, the solar generator 1 can cause light from the outside to propagate through the first light guide 4 so as to be guided to the solar cell 7. Moreover, the solar generator 1 can cause light that has passed through the first light guide 4 to propagate through the second light guide 5 so as to be guided to the solar cell 7. Furthermore, because the low-refractive-index layer 6 is disposed between the first light guide 4 and the second light guide 5, the refraction angle θ₅, at which a light beam that has passed through the first light guide 4 is refracted when the light beam enters the low-refractive-index layer 6, is larger than the incident angle θ₄, at which the light beam is incident on the gently inclined surface T_{1b} of the first light guide 4. Thus, a light-guide distance, which is the length of a path along which a light beam that has entered the low-refractive-index layer 6 is guided to the second light guide 5, can be increased. Therefore, the light beam, which has passed through the first light guide 4, is reflected a smaller number of times between the first light guide 4 and the second light guide 5 while being guided, and thereby the light can be easily guided to the solar cell 7. Therefore, with the solar cell module 2 and the solar generator 1 including the solar cell module 2, decrease in the power generation efficiency can be prevented.

The refractive index n₁ of the first light guide 4 is equal to the refractive index n₂ of the second light guide 5. The inclination angle of the first inclined surface of the first light guide 4 is equal to the inclination angle of the second inclined surface of the second light guide 5. Moreover, the first main surface 4a of the first light guide 4 is a flat surface, and the second main surface of the second light guide 5 is a flat surface that is parallel to the first main surface 4a. Therefore, light guides made of the same material and having the same size can be used as the first light guide 4 and the second light guide 5. For example, by preparing two first light guides and by inversely placing one of the first light guides so as to face the other first light guide with the low-refractive-index layer therebetween, the one of the first light guides can be used as the second light guide. Therefore, production cost can be reduced.

Because the spacers 9 are disposed between the first light guide 4 and the second light guide 5, the second main surface 4b of the first light guide 4 and the first main surface 5a of the second light guide 5 do not come into contact with each other, and the low-refractive-index layer 6 having a predetermined thickness can be interposed between the first light guide 4 and the second light guide 5. Therefore, light that has passed through the first light guide 4 can be prevented from entering the second light guide 5 without passing through the low-refractive-index layer 6. Therefore, reduction in the power generation efficiency can be stably prevented and the reliability can be improved.

Because the low-refractive-index layer 6 is an air layer, it is easy to make the refractive index of the low-refractive-index layer 6 sufficiently low. Therefore, light that has passed through the first light guide 4 can be easily guided to the solar cell 7.

The inventor carried out a simulation of the sunlight extraction ratio in order to demonstrate the effects of the solar generator 1 according to the present embodiment (see FIG. 16). Here, the term “sunlight extraction ratio” refers the ratio (%) of the amount of light that is concentrated on an end surface of the light guide module 3 (at least one of the first end surface 4c of the first light guide 4 and the first end surface 5c of the second light guide 5) to the total amount of sunlight (100%) that is incident on the first main surface 4a of the first light guide 4. The conditions of the simulation in example 1 were as follows: the horizontal dimensions of the first light guide 4 were 250 mm×250 mm, the thickness of the first light guide 4 was 10 mm, the horizontal dimensions of the second light guide 5 were 250 mm×250 mm, and the thickness of the second light guide 5 was 10 mm. The refractive index of the first light guide 4 was 1.5, the refractive index of the second light guide 5 was 1.5, and the refractive index of air was 1.0. For the solar cell module 2 of example 1, when sunlight was incident on the first main surface 4a side of the first light guide 4, the sunlight extraction ratio was 35.996%.

The output conditions of the solar cell 7 are standardized with respect to air mass AM1.5, which is specified in JIS. In this case, the incident angle at which sunlight is incident on the first main surface 4a of the first light guide 4 is approximately 42 degrees. As a comparative example, the simulation was performed by using only the first light guide 4 and without using the second light guide 5. The sunlight extraction ratio of the comparative example was 26.326%. Thus, with the solar generator 1 according to the present embodiment, the efficiency with which light is guided to the solar cell 7 was increased to about 1.4 times that of the case where the second light guide 5 was not used. As a result, it has been confirmed that the power generation efficiency can be improved.

### First Modification of First Embodiment

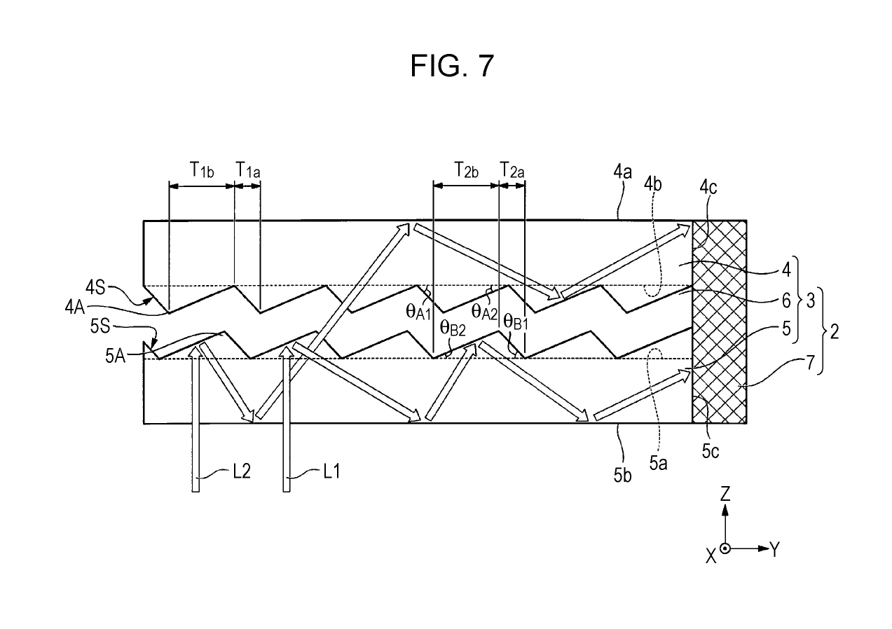

Referring to FIG. 7, a first modification of the present embodiment will be described.

The basic structure of a solar cell module according to the present modification is the same as that of the embodiment described above. Only the incident direction of sunlight differs from that of the embodiment described above.

FIG. 7 is a sectional view of a solar cell module 2 according to the present modification.

In FIG. 7, the elements the same as those in FIG. 3 for the embodiment described above will be denoted by the same numerals, and descriptions of such elements will be omitted. In FIG. 7, for convenience of drawing, only light beams that enter through the second main surface 5b of the second light guide 5 are illustrated. In the present modification, only light beams that enter through the second main surface 5b of the second light guide 5 will be described, and a description of light beams that enter through the first main surface 4a of the first light guide 4 will be omitted.

With the solar cell module 2 according to the present modification, light from the outside is incident not only on the first main surface 4a of the first light guide 4 but also on the second main surface 5b of the second light guide 5.

As illustrated in FIG. 7, the second light-direction changer 5S is disposed on the first main surface 5a of the second light guide 5. The second light-direction changer 5S reflects light that has entered through the second main surface 5b of the second light guide 5 and changes the propagation direction of the light to a direction toward the first end surface 5c. The second light-direction changer 5S includes the plurality of triangular-prism-shaped protrusions 5A, which are formed on the first main surface 5a of the second light guide 5.

Each of the protrusions 5A of the second light-direction changer 5S has second inclined surfaces (the steeply inclined surface T₂ₐ and the gently inclined surface T_{2b}). The steeply inclined surface T₂ₐ has the predetermined inclination angle θ_{B1} with respect to the first main surface 5a. The gently inclined surface T_{2b} has the inclination angle θ₃₂, which is smaller than the inclination angle θ_{B1} of the steeply inclined surface T₂ₐ, with respect to the first main surface 5a. These two inclined surface T₂ₐ and T_{2b} function as a reflecting surface for reflecting light that has entered through the second main surface 5b.

Each of the protrusions 4A of the first light-direction changer 4S has the steeply inclined surface T₁ₐ and the gently inclined surface T_{1b}. The steeply inclined surface T₁ₐ has the predetermined inclination angle θₘ with respect to the second main surface 4b. The gently inclined surface T_{1b} has the inclination angle θ_{A2}, which is smaller than the inclination angle θ_{A1} of the steeply inclined surface T₁ₐ, with respect to the second main surface 4b. These two first inclined surfaces T₁ₐ and T_{1b} function as a refracting surface for refracting light that has passed through the second light guide 5 and has entered the first light guide 4.

The solar cell module 2 according to the present modification 2 allows light to enter through both the first main surface 4a of the first light guide 4 and the second main surface 5b of the second light guide 5. Therefore, as compared with the structure that allows light to enter through one of the surfaces of the solar cell module 2, the efficiency with which light is guided to the solar cell 7 can be increased and the power generation efficiency can be improved.

### Second Embodiment

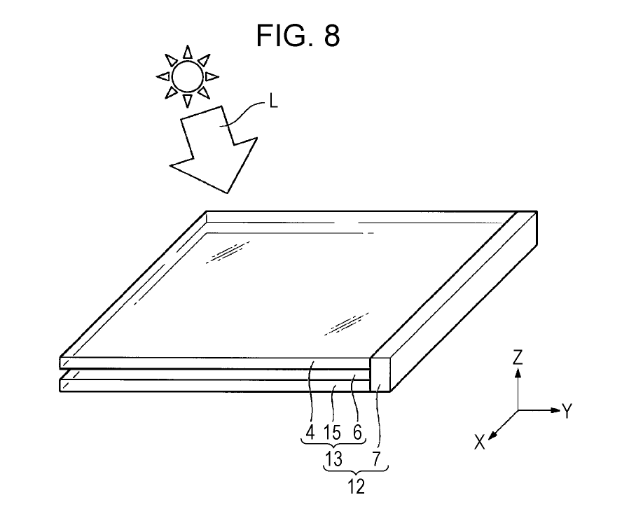

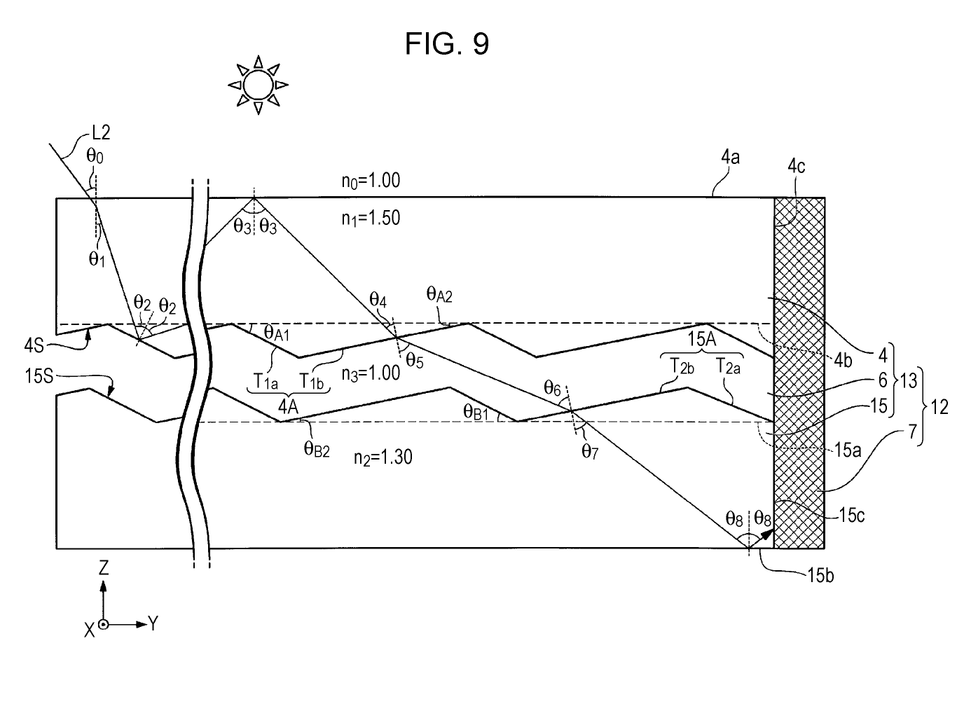

Referring to FIGS. 8 and 9, a second embodiment of the present invention will be described.

The basic structure of a solar cell module according to the present embodiment is the same as that of the first embodiment, and only the refractive index of the second light guide differs from that of the first embodiment.

FIG. 8 is a perspective view of a solar cell module according to the present embodiment.

FIG. 9 illustrates the function of a reflecting surface of the solar cell module.

In FIGS. 8 and 9, the elements the same as those in FIGS. 1 and 4 for the first embodiment will be denoted by the same numerals, and descriptions of such elements will be omitted. In FIG. 9, for convenience of drawing, only a light beam L2 that passes through the first light guide 4 and propagates through a second light guide 15 is illustrated. In the present embodiment, only the light beam L2, which passes through the first light guide 4 and propagates through the second light guide 15, will be described; and a description of a light beam L1 that does not pass through the first light guide 4 and propagates only through the first light guide 4 will be omitted.

In a solar cell module 12 according to the present embodiment, the refractive index n₂ of the second light guide 15 is smaller than the refractive index n₁ of the first light guide 4 (n₂<n₁). The second light guide 15 may be made of a low-refractive index material, such as an amorphous fluoropolymer having a refractive index of about 1.3. As in the first embodiment, the first light guide 4 is made of an acrylic resin (refractive index 1.5), and the low-refractive-index layer 6 is an air layer (refractive index 1.0).

As illustrated in FIG. 9, a light beam is totally internally reflected by the steeply inclined surface T₁ₐ of the first light guide 4 at a reflection angle θ₂, and is reflected a predetermined times between the first main surface 4a and the second main surface 4b. Then, the light beam is incident on the first main surface 4a at an incident angle θ₃, and is totally internally reflected at a reflection angle θ₃. The light beam, which has been totally internally reflected by the first main surface 4a at the reflection angle θ₃, is incident on the gently inclined surface T_{1b} at an incident angle θ₄, is refracted at a refraction angle θ₅, and is incident on the gently inclined surface T_{2b} of the second light guide 15 at an incident angle θ₆. The light beam, which is incident on the gently inclined surface T_{2b} at the incident angle θ₆, is refracted by the gently inclined surface T_{2b} of the second light guide 15 at a refraction angle θ₇ when entering the second light guide 15. In this case, according to Snell's law, the refraction angle θ₇ at the gently inclined surface T₂₁₄ is larger than the incident angle θ₄ at the gently inclined surface T_{1b} (θ₇>θ₄). The light beam is incident on a second main surface 15b of the second light guide 15 at an incident angle θ₈, and is totally internally reflected by the second main surface 15b at a reflection angle θ₈. In this case, according to Snell's law, the reflection angle θ₈ of the light beam at the second main surface 15b is larger than the reflection angle θ₃ at the first main surface 4a (θ₈>θ₃). Subsequently, the light beam, which has been totally internally reflected by the second main surface 15b at the reflection angle θ₈, propagates through the second light guide 15, and is emitted toward the solar cell 7.

In the solar cell module 12 according to the present embodiment, the refractive index n₂ of the second light guide 15 is smaller than the refractive index n₁ of the first light guide 4. Therefore, according to Snell's law, the reflection angle θ₈, at which the light beam that has passed through the first light guide 4 is totally internally reflected by the second main surface 5b of the second light guide 15, is larger than the reflection angle θ₃, at which the light beam is reflected by the first main surface 4a of the first light guide 4. Thus, the light-guide distance, which is the length of a path along which the light beam that has entered the second light guide 15 is guided to the solar cell 7, can be made longer than that of the structure of the first embodiment. Moreover, the number of times the light beam is reflected between a first main surface 15a and the second main surface 15b can be reduced. Therefore, light that has entered the second light guide 15 can be easily guided to the solar cell 7. Therefore, reduction in the power generation efficiency can be prevented.

The inventor carried out a simulation of the sunlight extraction ratio in order to demonstrate the effects of the solar cell module 12 according to the present embodiment (see FIG. 16). The conditions of the simulation in example 2 were as follows: the horizontal dimensions of the first light guide 4 were 250 mm×250 mm, the thickness of the first light guide 4 was 10 mm, the horizontal dimensions of the second light guide 15 were 250 mm×250 mm, and the thickness of the second light guide 15 was 10 mm. The refractive index of the first light guide 4 was 1.5, the refractive index of the second light guide 15 was 1.3, and the refractive index of air was 1.0. For the solar cell module 12 of example 2, when sunlight was incident on the first main surface 4a side of the first light guide 4, the sunlight extraction ratio was 37.232%.

The output conditions of the solar cell 7 are standardized with respect to air mass AM1.5, which is specified in JIS. In this case, the incident angle at which sunlight is incident on the first main surface 4a of the first light guide 4 is approximately 42 degrees. As a comparative example, the simulation is performed by using only the first light guide 4 and without using the second light guide 15. The sunlight extraction ratio of the comparative example was 26.326%. Thus, with the solar cell module 12 according to the present embodiment, the efficiency with which light is guided to the solar cell 7 was increased to about 1.4 times that of the case where the second light guide 15 was not used. As a result, it has been confirmed that the power generation efficiency can be improved.

### Third Embodiment

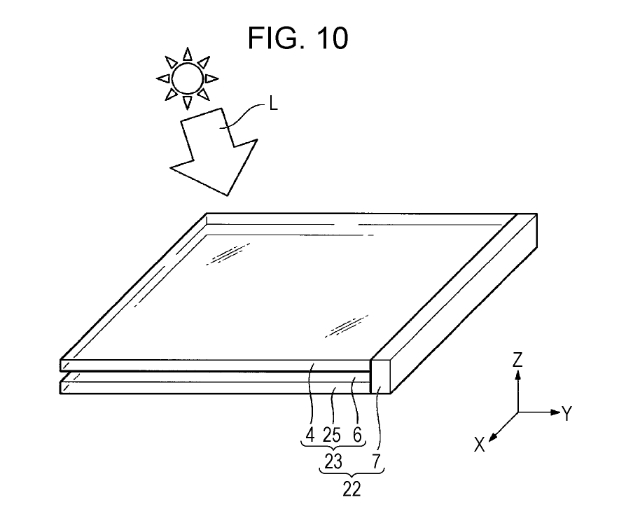

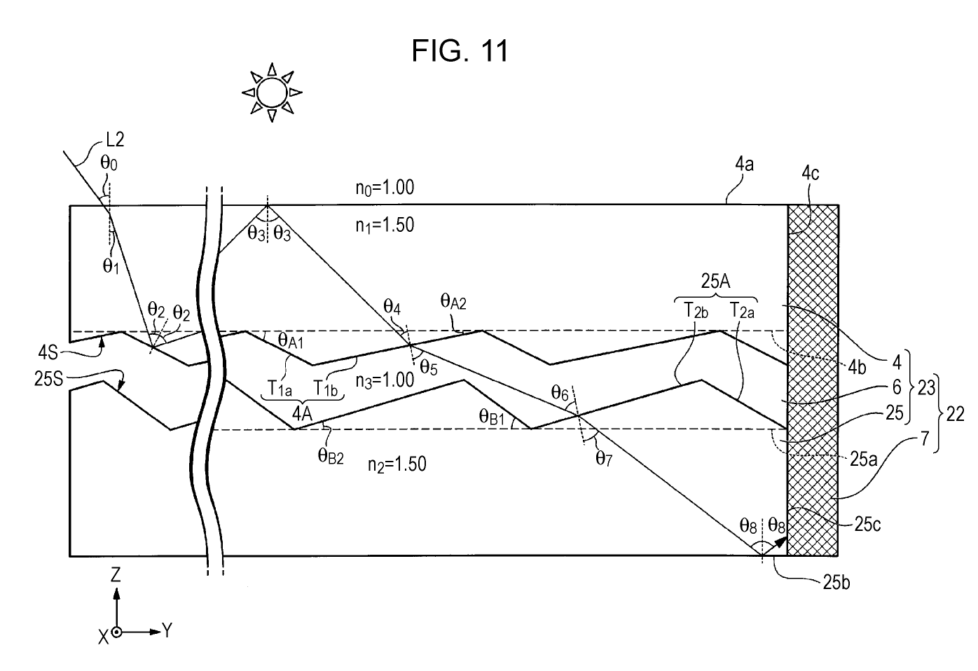

Referring to FIGS. 10 and 11, a third embodiment of the present invention will be described.

The basic structure of a solar cell module according to the present embodiment is the same as that of the first embodiment, except that the inclination angle of the second inclined surface of the second light guide differs from that of the first embodiment.

FIG. 10 is a perspective view of a solar cell module according to the present embodiment.

FIG. 11 illustrates the function of a reflecting surface of the solar cell module.

In FIGS. 10 and 11, the elements the same as those in FIGS. 1 and 4 for the first embodiment will be denoted by the same numerals, and descriptions of such elements will be omitted. In FIG. 11, for convenience of drawing, only a light beam L2 that passes through the first light guide 4 and propagates through a second light guide 25 is illustrated. In the present embodiment, only the light beam L2, which passes through the first light guide 4 and propagates through the second light guide 25, will be described; and a description of a light beam L1 that does not pass through the first light guide 4 and propagates only through the first light guide 4 will be omitted.

As illustrated in FIG. 11, in a solar cell module 22 according to the present embodiment, the inclination angles of the second inclined surfaces of the second light guide 25 are larger than those of the first inclined surfaces of the first light guide 4. To be specific, the inclination angle θ_{B1} of the steeply inclined surface T₂ₐ of the second light guide 25 is larger than the inclination angle θ_{A1} of the steeply inclined surface T₁ₐ of the first light guide 4; and the inclination angle θ_{B2} of the gently inclined surface T_{2b} of the second light guide 25 is larger than the inclination angle θ_{A2} of the gently inclined surface T_{1b} of the first light guide 4. As in the first embodiment, the first light guide 4 and the second light guide 25 are made of an acrylic resin (refractive index 1.5), and the low-refractive-index layer 6 is an air layer (refractive index 1.0).

As illustrated in FIG. 11, a light beam is totally internally reflected by the steeply inclined surface T₁ₐ of the first light guide 4 at a reflection angle θ₂ and is reflected a predetermined times between the first main surface 4a and the second main surface 4b. Then, the light beam is incident on the first main surface 4a at an incident angle θ₃, and is totally internally reflected at a reflection angle θ₃. The light beam, which has been totally internally reflected by the first main surface 4a at the reflection angle θ₃, is incident on the gently inclined surface T_{1b} at an incident angle θ₄, is refracted at a refraction angle θ₅, and is incident on the gently inclined surface T_{2b} of the second light guide 25 at an incident angle θ₆. The light beam, which is incident on the gently inclined surface T_{2b} at the incident angle θ₆, is refracted by the gently inclined surface T_{2b} of the second light guide 25 at a refraction angle θ₇ when entering the second light guide 25. The light beam is incident on a second main surface 25b of the second light guide 25 at an incident angle θ₈, and is totally internally reflected by the second main surface 25b at a reflection angle θ₈. In this case, because the inclination angle θ_{B1} of the steeply inclined surface T2a of the second light guide 25 is larger than the inclination angle θ_{A1} of the steeply inclined surface T₁ₐ of the first light guide 4, the reflection angle θ₈ of the light beam at the second main surface 25b is larger than the reflection angle θ₃ at the first main surface 4a (θ₈>θ₃). Subsequently, the light beam, which has been totally internally reflected by the second main surface 25b at a reflection angle θ₈, propagates through the second light guide 25, and is emitted toward the solar cell 7.

In the solar cell module 22 according to the present embodiment, the inclination angles of the inclined surfaces of the second light guide 25 are larger than those of the first light guide 4. Therefore, the reflection angle θ₈, at which the light beam that has passed through the first light guide 4 is reflected by the second main surface 25b of the second light guide 25, is larger than the reflection angle θ₃, at which the light beam is reflected by the first main surface 4a of the first light guide 4. Thus, the light-guide distance, which is the length of a path along which the light beam that has entered the second light guide 25 is guided to the solar cell 7, can be made longer than that of the structure of the first embodiment. Moreover, the number of times the light beam is reflected between a first main surface 25a and the second main surface 25b can be reduced. Therefore, light that has entered the second light guide 25 can be easily guided to the solar cell 7. Therefore, reduction in the power generation efficiency can be prevented.

The inventor carried out a simulation of the sunlight extraction ratio in order to demonstrate the effects of the solar cell module 22 according to the present embodiment (see FIG. 16). The conditions of the simulation in example 3 were as follows: the horizontal dimensions of the first light guide 4 were 250 mm×250 mm, the thickness of the first light guide 4 was 10 mm, the horizontal dimensions of the second light guide 25 were 250 mm×250 mm, and the thickness of the second light guide 25 was 10 mm. The refractive index of the first light guide 4 was 1.5, the refractive index of the second light guide 25 was 1.5, and the refractive index of air was 1.0. The inclination angles of the second inclined surfaces of the second light guide 25 were larger than those of the first inclined surfaces of the first light guide 4. For the solar cell module 22 of example 3, when sunlight was incident on the first main surface 4a side of the first light guide 4, the sunlight extraction ratio was 35.976%.

The output conditions of the solar cell 7 are standardized with respect to air mass AM1.5, which is specified in JIS. In this case, the incident angle at which sunlight is incident on the first main surface 4a of the first light guide 4 is approximately 42 degrees. As a comparative example, the simulation is performed by using only the first light guide 4 and without using the second light guide 25. The sunlight extraction ratio of the comparative example was 26.326%. Thus, with the solar cell module 22 according to the present embodiment, the efficiently with which light is guided to the solar cell 7 was increased to about 1.4 times that of the case where the second light guide 25 was not used. As a result, it has been confirmed that the power generation efficiency can be improved.

### Fourth Embodiment

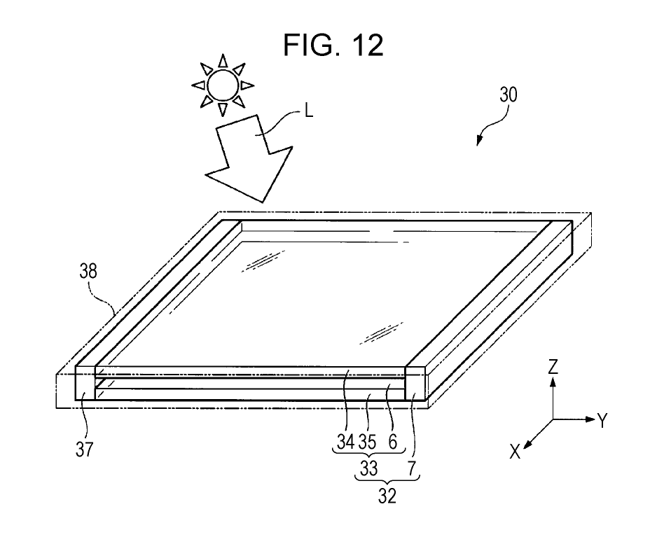

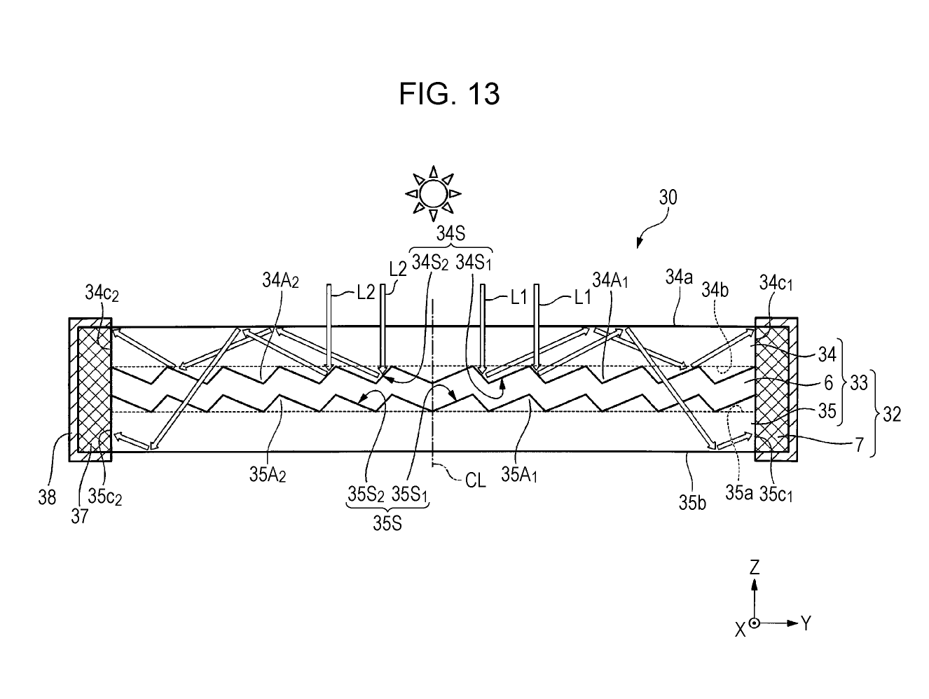

Referring to FIGS. 12 and 13, a fourth embodiment of the present invention will be described.

FIG. 12 is a perspective view of a solar generator according to the present embodiment.

FIG. 13 is a sectional view of the solar generator.

In FIGS. 12 and 13, the elements the same as those in FIGS. 1 and 2 for the first embodiment will be denoted by the same numerals, and descriptions of such elements will be omitted.

As illustrated in FIG. 13, the structure of a part of a solar generator 30 according to the present embodiment on the right side (±Y side) of the center line CL is the same as that of the first embodiment. However, the structure of a part of the solar generator 30 on the left side (−Y side) of the center line CL is different from that of the first embodiment. That is, the solar generator 30 is symmetric with respect to the center line CL. In other respects, the fourth embodiment is the same as the first embodiment.

As illustrated in FIGS. 12 and 13, the solar generator 30 includes a solar cell module 32, a solar cell 37, and a support frame 38. The support frame 38 has a substantially rectangular shape in plan view, and is attached to the solar cell module 32 and the solar cell 37 so as to surround the solar cell module 32 and the solar cell 37.

The solar cell module 32 includes a light guide module 33 and a solar cell 7. In the solar cell module 32, light that has entered the light guide module 33 is guided to the solar cells 7 and 37. The solar cells 7 and 37 perform photoelectric conversion and output electric energy.

The light guide module 33 includes a first light guide 34, a second light guide 35, and a low-refractive-index layer 6. The first light guide 34 has a second end surface 34c₂ that is connected to a first main surface 34a and a second main surface 34b and that faces a first end surface 34c₁. The second light guide 35 has a second end surface 35c₂ that is connected to a first main surface 35a and a second main surface 35b and that faces a first end surface 35c₁.

A first light-direction changer 34S is disposed on the second main surface 34b of the first light guide 34. The first light-direction changer 34S reflects light that has entered through the first main surface 34a and changes the propagation direction of the light. The first light-direction changer 34S includes a first-end-side reflector 34S₁, which reflects a light beam L1 that has entered through the first main surface 34a toward the first end surface 34c₁, and a second-end-side reflector 34S₂, which reflects a light beam L2 that has entered through the first main surface 34a toward the second end surface 34c₂. In the first light-direction changer 34S, the area of the reflecting surface of the first-end-side reflector 34S₁ is equal to the area of the reflecting surface of the second-end-side reflector 34S₂.

The first-end-side reflector 34S₁ includes a plurality of triangular-prism-shaped protrusions 34A₁ that are formed on a part of the second main surface 34b of the first light guide 34 on the right side (+Y side) of the center line CL. The second-end-side reflector 34S₂ includes a plurality of triangular-prism-shaped protrusions 34A₂ that are formed on a part of the second main surface 34b of the first light guide 34 on the left side (−Y side) of the center line CL. The protrusions 34A₁ and the protrusions 34A₂ have shapes that are symmetric with respect to the center line CL. Some of light beams that have entered through various portions of the first main surface 34a of the first light guide 34 are reflected by the first-end-side reflector 345₁ and propagate through the first light guide 34 so as to be concentrated on a portion of the first end surface 34c₁ on which the solar cell 7 is disposed. The remainder of the light beams are reflected by the second-end-side reflector 34S₂ and propagate through the first light guide 34 so as to be concentrated on a portion of the second end surface 34c₂ on which the solar cell 37 is disposed.

A second light-direction changer 35S is disposed on the first main surface 35a of the second light guide 35. The second light-direction changer 35S refracts a light beam that has passed through the first light guide 34 and entered through the first main surface 35a thereof, and changes the propagation direction of the light beam. The second light-direction changer 35S includes a first-end-side refractor 35S₁, which refracts a light beam that has entered through the first main surface 35a toward the first end surface 35c₁, and a second-end-side refractor 35S₂, which refracts a light beam that has entered through the first main surface 35a toward the second end surface 35c₂. In the second light-direction changer 35S, the area of the refracting surface of the first-end-side refractor 35S₁ is equal to the area of the refracting surface of the second-end-side refractor 35S₂.

The first-end-side refractor 35S₁ includes a plurality of triangular-prism-shaped protrusions 35A₁ that are formed on a part of the first main surface 35a of the second light guide 35 on the right side (+Y side) of the center line CL. The second-end-side refractor 35S₂ includes a plurality of triangular-prism-shaped protrusions 35A₂ that are formed on a part of the first main surface 35a of the second light guide 35 on the left side (−Y side) of the center line CL. The protrusions 35A₁ and the protrusions 35A₂ have shapes that are symmetric with respect to the center line CL. Some of light beams that have passed through the first light guide 34 and that are incident on various positions on the first main surface 35a of the second light guide 35 are refracted by the first-end-side refractor 355₁ and propagate through the second light guide 35 so as to be concentrated on a portion of the first end surface 35c₁ on which the solar cell 7 is disposed. The remainder of the light beams are refracted by the second-end-side refractor 35S₂ and propagate through the second light guide 35 so as to be concentrated on a portion of the second end surface 35c₂ on which the solar cell 37 is disposed.

With the solar generator 30 according to the present embodiment, even when light beams having different angular components are incident on the first main surface 34a of the first light guide 34, the light beams that have entered through the first main surface 34a can be reflected toward the first end surface 34c₁ and toward the second end surface 34c₂. Therefore, when installing the solar generator 30, it is not necessary to consider the direction of the sun. For example, when the solar generator 30 is installed so as to face the east, until the sun reaches the highest point (from morning to noon), the first-end-side reflector 34S₁ reflects sunlight so that the sunlight can be concentrated on the solar cell 7. Until sunset (from noon to evening), the second-end-side reflector 34S₂ reflects sunlight so that the sunlight can be concentrated on the solar cell 37. In contrast, with a structure including only one of the first-end-side reflector 34S₁ and the second-end-side reflector 34S₂, from sunrise to sunset, light that enters through the first main surface 34a is concentrated on only one of the solar cell 7 and the solar cell 37. Therefore, with the solar generator 30 according to the present embodiment, from sunrise to sunset, light that enters through the first main surface 34a can be guided to both of the solar cell 7 and the solar cell 37.

In the first light-direction changer 34S, the area of the reflecting surface of the first-end-side reflector 34S₁ is equal to the area of the reflecting surface of the second-end-side reflector 34S₂. Therefore, from sunrise to sunset, light that enters through the first main surface 34a can be guided to the solar cell 7 and the solar cell 37 in a well-balanced manner.

### Fifth Embodiment

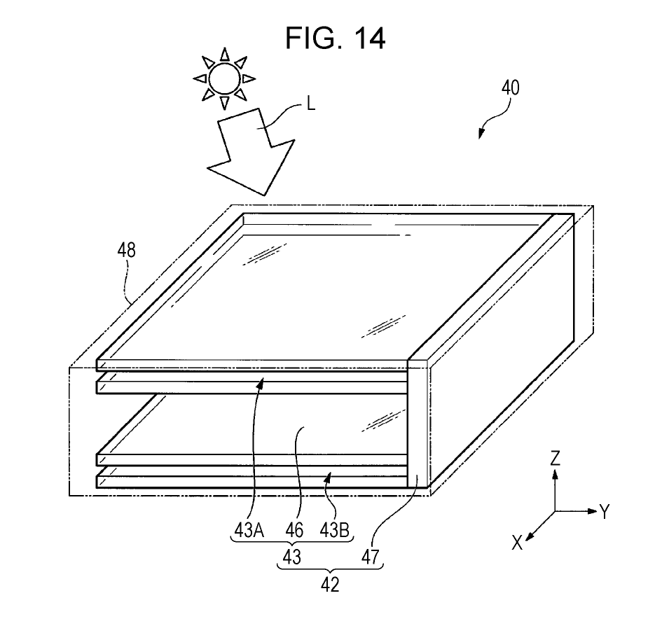

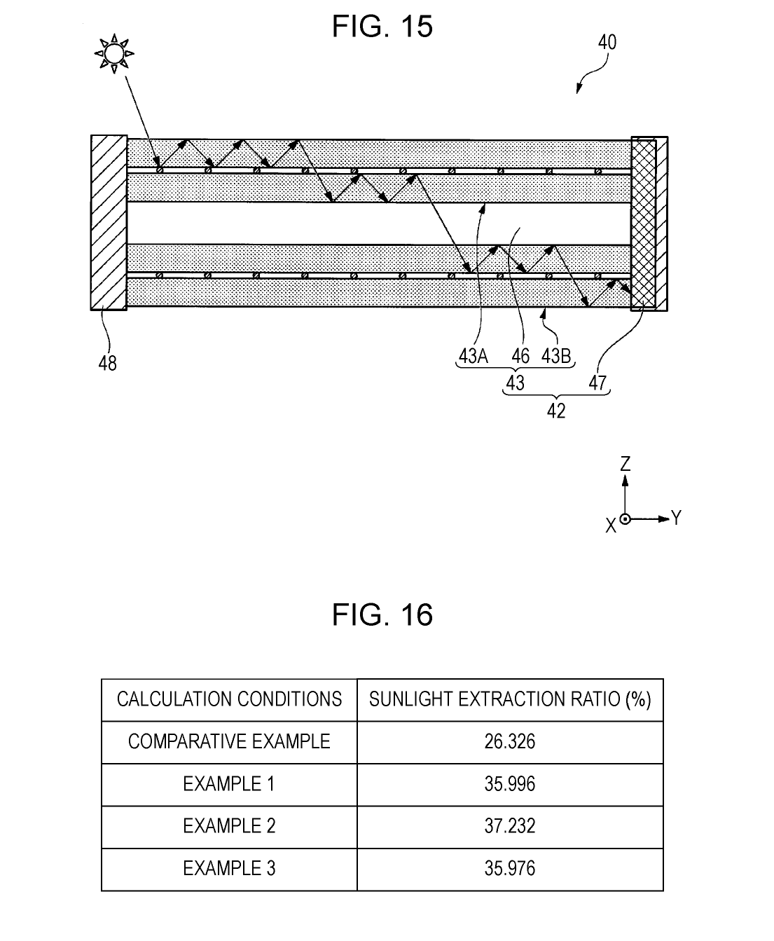

Referring to FIGS. 14 and 15, a fifth embodiment of the present invention will be described.

The basic structure of a solar generator according to the present embodiment is the same as that of the first embodiment. Only the number of light guide modules differs from that of the first embodiment.

FIG. 14 is a schematic perspective view of a solar generator according to the present embodiment.

FIG. 15 is a sectional view of the solar generator. In FIGS. 14 and 15, the elements the same as those in FIGS. 1 and 2 for the first embodiment will be denoted by the same numerals, and descriptions of such elements will be omitted.

As illustrated in FIG. 14, a solar generator 40 according to the present embodiment includes a plurality of (in this example, two) light guide modules 3, which face each other with a low-refractive-index layer 46 therebetween. The number of light guide modules 3 may be two, three, or more.

The solar generator 40 includes a solar cell module 42 and a support frame 48. The support frame 48 has a substantially rectangular shape in plan view and surrounds the solar cell module 42. The solar cell module 42 includes a light guide unit 43 and a solar cell 47. The light guide unit 43 includes a first light guide module 3A, a second light guide module 3B, and the low-refractive-index layer 46. As necessary, spacers may be disposed between the first light guide module 3A and the second light guide module 3B.

As illustrated in FIG. 15, some of light beams that have entered a first light guide module 43A propagate through the first light guide module 43A, are guided to the solar cell 47, and contribute to power generation. The remainder of the light beams are emitted from the first light guide module 43A, propagate through a second light guide module 43B, are guided to the solar cell 47, and contribute to power generation.

With the solar generator 40 according to the present embodiment, light from the outside can be made to propagate through the first light guide module 43A and can be guided to the solar cell 47. Moreover, light that has passed through the first light guide module 43A can be made to propagate through the second light guide module 43B and can be guided to the solar cell 47. Therefore, reduction in the power generation efficiency can be reliably prevented.

The scope of the present invention is not limited to the embodiments described above, and the embodiments can be modified in various ways within the spirit and scope of the present invention.

For example, in the embodiments described above, a plate-shaped member is used as the light guide. However, the shape of the light guide is not limited to a plate-like shape and may be, for example, a bar-like shape. The shape may be changed as appropriate. Moreover, the shapes, the dimensions, the numbers, the dispositions, the materials, and the manufacturing method of the elements in the embodiments described above are not limited to those used as examples in the embodiments, and may be modified as appropriate.

### INDUSTRIAL APPLICABILITY

The present invention can be used for solar cell modules or solar generators.

### REFERENCE SIGNS LIST

1, 30, 40 solar generator
2, 12, 22, 32, 42 solar cell module
3, 3A, 3B, 13, 23, 33 light guide module
4, 34 first light guide
4a, 34a first main surface of first light guide
4b, 34b second main surface of first light guide
4c, 34c₁ first end surface of first light guide
4S, 34S first light-direction changer
5, 15, 25, 35 second light guide
5a, 15a, 25a, 35a first main surface of second light guide
5b, 15b, 25b, 35b second main surface of second light guide
5c, 15c, 25c, 35c₁ first end surface of second light guide
5S, 15S, 25S, 35S second light-direction changer
6 low-refractive-index layer
7, 37, 47 solar cell
9 spacer
34S₁ first-end-side reflector
34c₂ second end surface of first light guide
34S₂ second-end-side reflector
35c₂ second end surface of second light guide
n₁ refractive index of first light guide
n₂ refractive index of second light guide
T₁ₐ, T_{2b} first inclined surface
T₂ₐ, T_{2b} second inclined surface
θ_{A1}, θ_{A2} inclination angle of first inclined surface (first inclination angle)
θ_{B1}, θ_{B2} inclination angle of second inclined surface (second inclination angle)

1. A solar cell module comprising:
a light guide module including a first light guide and a second light guide that are disposed so as to face each other and a low-refractive-index layer that is disposed between the first light guide and the second light guide;
a solar cell that receives light emitted from the light guide module; and
a spacer that is disposed between the first light guide and the second light guide, the spacer maintaining a distance between the first light guide and the second light guide,
wherein the first light guide has a first main surface, a second main surface, and a first end surface that is connected to the first main surface and the second main surface, and the first light guide allows a first light beam from the outside to enter thereinto through the first main surface, to propagate therethrough, and to be emitted from the first end surface,
wherein the second light guide has a first main surface, a second main surface, and a first end surface that is connected to the first main surface and the second main surface, and the second light guide allows a second light beam that has passed through the first light guide to enter thereinto through the first main surface of the second light guide, to propagate therethrough, and to be emitted from the first end surface of the second light guide,
wherein the low-refractive-index layer has a refractive index that is lower than a refractive index of any of the first light guide and the second light guide,
wherein the solar cell receives the first light beam emitted from the first end surface of the first light guide and the second light beam emitted from the first end surface of the second light guide,
wherein the second main surface of the first light guide includes a first reflecting surface that reflects the first light beam and changes a propagation direction of the first light beam, which has entered through the first main surface of the first light guide, and
wherein the second main surface of the second light guide includes a second reflecting surface that reflects the second light beam and changes a propagation direction of the second light beam, which has entered through the first main surface of the first light guide, has passed through the first light guide, has been refracted by the low-refractive-index layer, and has entered the second light guide.

2. The solar cell module according to claim 1, wherein the second main surface of the first light guide includes a first light-direction changer that reflects the first light beam and changes the propagation direction of the first light beam, which has entered through the first main surface of the first light guide, and
wherein the first light-direction changer has a first inclined surface that is inclined at a first inclination angle with respect to the second main surface of the first light guide, and the first inclined surface serves as the first reflecting surface for reflecting the first light beam, which has entered through the first main surface of the first light guide.

3. The solar cell module according to claim 2, wherein the first main surface of the second light guide includes a second light-direction changer that reflects a third light beam that has entered through the second main surface of the second light guide and that changes a propagation direction of the third light beam, and
wherein the second light-direction changer has a second inclined surface that is inclined at a second inclination angle with respect to the first main surface of the second light guide, and the second inclined surface reflects the third light beam, which has entered through the second main surface of the second light guide.

4. The solar cell module according to claim 3, wherein the first inclination angle is equal to or smaller than the second inclination angle.

5. (canceled)

6. The solar cell module according to claim 1, wherein the first main surface of the first light guide is a flat surface, and
wherein the second main surface of the second light guide is a flat surface that is parallel to the first main surface.

7. The solar cell module according to claim 1, wherein the refractive index of the first light guide is equal to the refractive index of the second light guide.

8. The solar cell module according to claim 1, wherein the refractive index of the second light guide is smaller than the refractive index of the first light guide.

9. (canceled)

10. The solar cell module according to claim 1, wherein the low-refractive-index layer is an air layer.

11. The solar cell module according to claim 2, wherein the first light guide has a second end surface that is connected the first main surface and the second main surface and that faces the first end surface, and
wherein the first light-direction changer includes a first-end-side reflector that reflects a fourth light beam toward the first end surface and a second-end-side reflector that reflects a fifth light beam toward the second end surface, the fourth light beam having entered through the first main surface of the first light guide, and the fifth light beam having entered through the first main surface of the first light guide.

12. The solar cell module according to claim 11, wherein, in the first light-direction changer, the area of a reflecting surface of the first-end-side reflector is equal to the area of a reflecting surface of the second-end-side reflector.

13. The solar cell module according to claim 1, comprising a plurality of light guide modules each having the same structure as the light guide module, the plurality of light guide modules being disposed so as to face each other.

14. A solar generator comprising the solar cell module according to claim 1.

15. A solar cell module comprising:
a light guide module including a first light guide and a second light guide that are disposed so as to face each other and a low-refractive-index layer that is disposed between the first light guide and the second light guide; and
a solar cell that receives light emitted from the light guide module,
wherein the first light guide has a first main surface, a second main surface, and a first end surface that is connected to the first main surface and the second main surface, and the first light guide allows a first light beam from the outside to enter thereinto through the first main surface, to propagate therethrough, and to be emitted from the first end surface,
wherein the second light guide has a first main surface, a second main surface, and a first end surface that is connected to the first main surface and the second main surface, and the second light guide allows a second light beam that has passed through the first light guide to enter thereinto through the first main surface of the second light guide, to propagate therethrough, and to be emitted from the first end surface of the second light guide,
wherein a refractive index of the second light guide is smaller than a refractive index of the first light guide,
wherein the low-refractive-index layer has a refractive index that is lower than the refractive index of any of the first light guide and the second light guide,
wherein the solar cell receives the first light beam emitted from the first end surface of the first light guide and the second light beam emitted from the first end surface of the second light guide,
wherein the second main surface of the first light guide includes a first reflecting surface that reflects the first light beam and changes a propagation direction of the first light beam, which has entered through the first main surface of the first light guide, and
wherein the second main surface of the second light guide includes a second reflecting surface that reflects the second light beam and changes a propagation direction of the second light beam, which has entered through the first main surface of the first light guide, has passed through the first light guide, has been refracted by the low-refractive-index layer, and has entered the second light guide.

16. The solar cell module according to claim 15, wherein the second main surface of the first light guide includes a first light-direction changer that reflects the first light beam and changes the propagation direction of the first light beam, which has entered through the first main surface of the first light guide, and
wherein the first light-direction changer has a first inclined surface that is inclined at a first inclination angle with respect to the second main surface of the first light guide, and the first inclined surface serves as the first reflecting surface for reflecting the first light beam, which has entered through the first main surface of the first light guide.

17. The solar cell module according to claim 16, wherein the first main surface of the second light guide includes a second light-direction changer that reflects a third light beam that has entered through the second main surface of the second light guide and that changes a propagation direction of the third light beam, and
wherein the second light-direction changer has a second inclined surface that is inclined at a second inclination angle with respect to the first main surface of the second light guide, and the second inclined surface reflects the third light beam, which has entered through the second main surface of the second light guide.

18. The solar cell module according to claim 17, wherein the second inclination angle is larger than the first inclination angle.

19. The solar cell module according to claim 15, wherein the first main surface of the first light guide is a flat surface, and
wherein the second main surface of the second light guide is a flat surface that is parallel to the first main surface.

20. The solar cell module according to claim 15, wherein the low-refractive-index layer is an air layer.

21. The solar cell module according to claim 16, wherein the first light guide has a second end surface that is connected the first main surface and the second main surface and that faces the first end surface, and
wherein the first light-direction changer includes a first-end-side reflector that reflects a fourth light beam toward the first end surface and a second-end-side reflector that reflects a fifth light beam toward the second end surface, the fourth light beam having entered through the first main surface of the first light guide, and the fifth light beam having entered through the first main surface of the first light guide.

22. The solar cell module according to claim 20, wherein, in the first light-direction changer, the area of a reflecting surface of the first-end-side reflector is equal to the area of a reflecting surface of the second-end-side reflector.
